(19) United States
(12) Patent Application Publication
(10) Pub. No.: US 2008/0277063 A1
(43) Pub. Date: Nov. 13, 2008

(54) Apparatus for treating substrate using plasma

(76) Inventor: Tae Ho Shin, Gyeonggi-do (KR)

Correspondence Address: HARNESS, DICKEY & PIERCE, P.L.C., P.O. BOX 8910, RESTON, VA, 20195, US

(21) Appl. No.: 11/882,156

(22) Filed: Jul. 31, 2007

(30) Foreign Application Priority Data
May 10, 2007 (KR) 10-2007-0045711

(51) Int. Cl. H05H 1/02; C23C 16/00

(52) U.S. Cl. 156/345.29; 118/723 R

(57) ABSTRACT

The, present invention is directed to an apparatus for treating a substrate using plasma. To improve plasma characteristics, magnetic units are provided for supplying a magnetic field. A first magnet unit is provided at an upper region among a lateral portion of a housing, and a second magnet unit is provided at a lower portion. Each of the magnet units includes a plurality of electromagnets disposed to exhibit the shape of a regular polygon, when viewed from the upside. An underlying magnet unit is disposed to rotate on its axis at a predetermined angle from a position of alignment with an overlying magnet. According to the above configuration, a uniformity of plasma inside the housing is improved and, especially, it is possible to prevent plasma uniformity from decreasing at a region between adjacent electromagnets.

### CROSS-REFERENCE TO RELATED APPLICATIONS

This U.S. non-provisional patent application claims priority under 35 U.S.C §119 of Korean Patent Application 2007-45711 filed on May 10, 2007, the entirety of which is hereby incorporated by reference.

### BACKGROUND

The present invention relates to substrate treating apparatuses and, more particularly, to an apparatus for treating a substrate using plasma.

Various processes are required to manufacture a semiconductor device. During a number of processes including deposition, etching, and cleaning processes, plasma is generated from gas and supplied onto a semiconductor substrate such as a wafer to deposit a thin film on the wafer or remove a thin film such as oxide or contaminants from the wafer.

In the present time, two methods have been employed to provide a magnetic field from a plasma treating apparatus. One method is that a permanent magnet is used to supply a magnetic field, and the other is that an electromagnet is used to supply a magnetic field. In the case where a permanent magnet is used to supply a magnetic field, an optimized magnetic field for a specific process may be provided but it is difficult to change shape or intensity of the magnetic field. In the case where an electromagnet is used to supply a magnetic field, shape or intensity of the magnetic field may freely be controlled but it is difficult to provide an optimized magnetic field due to the limitation of magnet layout. U.S. Pat. No. 5,215,619 discloses a plasma etching apparatus where four magnets are arranged around a chamber. In the case where an apparatus having such a configuration is used, there is a limitation to enhancement of plasma density uniformity and, especially, an etch uniformity at a wafer region corresponding to a region between adjacent magnets is much lower than at the other regions.

### SUMMARY OF THE INVENTION

Exemplary embodiments of the present invention are directed to plasma treating apparatuses. In an exemplary embodiment, the plasma treating apparatus may include: a housing in which a space is provided to house a substrate; a gas supply member provided to supply a gas into the housing; a plasma source for generating plasma from the gas supplied into the housing; and a magnetic field formation member provided to supply a magnetic field at a region where plasma is generated inside the housing, wherein the magnetic field formation member comprises: a first magnet unit disposed around the housing; and a second magnet unit disposed around the housing and provide to be partitioned from the first magnet unit by a layer.

In another exemplary embodiment, the plasma treating apparatus may include: a housing where a plasma process is performed; a plasma source provided into the housing to generate plasma from a gas supplied into the housing; and at least two magnet units disposed to surround the circumference of the housing and provided to be partitioned by layers, wherein each of the magnet units includes a plurality of electromagnets disposed to exhibit a shape surrounding a lateral portion of the housing, and wherein the electromagnets provided at adjacent layers are arranged to be asymmetrical with respect to a surface running between the electromagnets.

### BRIEF DESCRIPTION OF THE DRAWINGS

FIG. 1 is a top plan view illustrating an example of a substrate treating apparatus.

FIG. 2 is a cross-sectional view of the configuration of a plasma treating apparatus illustrated in FIG. 1.

FIG. 3 is a perspective view of the plasma treating apparatus illustrated in FIG. 2.

FIG. 4 is a perspective view of a magnetic field formation member illustrated in FIG. 3.

FIG. 5 is a top plan view of FIG. 2.

FIGS. 6A through 7B show a relationship between uniformity of magnetic field magnitude and uniformity of plasma density.

FIGS. 8A through 9C show the magnitude of a magnetic field and plasma density when a typical plasma treating apparatus is used and when the plasma treating apparatus illustrated in FIG. 3 is used.

FIGS. 10 through 13 show various modified examples of a plasma treating apparatus according to the present invention.

### DETAILED DESCRIPTION OF PREFERRED EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes of elements or components are exaggerated for clarity.

In this embodiment, a wafer will now be exemplarily described as a plasma treating target and a plasma treating apparatus using capacitively coupled plasma as plasma source will now be described. However, the embodiments of the present invention are not limited to those mentioned above and the plasma treating target may be another kind of substrate such as a glass substrate, and the plasma source may be inductively coupled plasma.

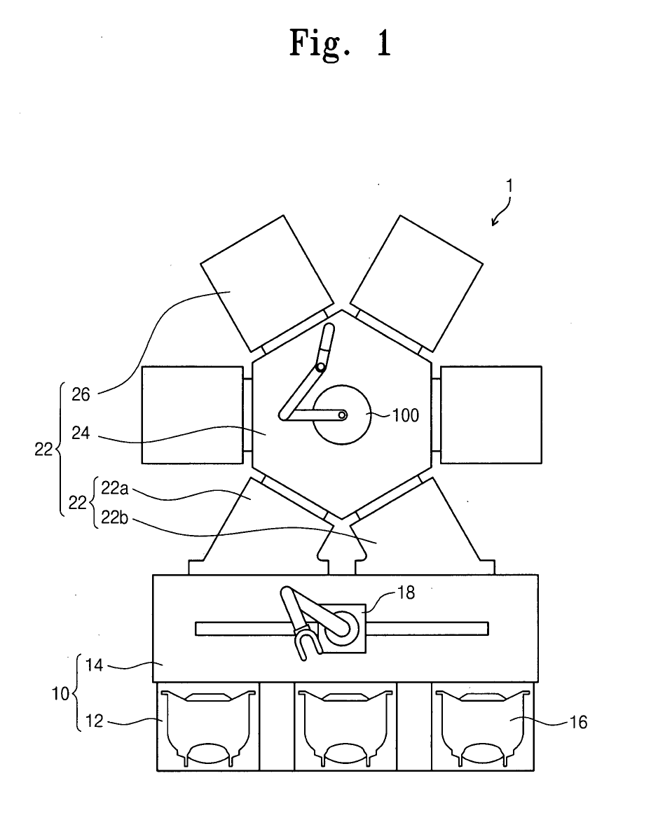

FIG. 1 is a top plan view illustrating an example of a substrate treating apparatus 1 according to an embodiment of the present invention. The substrate treating apparatus 1 includes an equipment front end module 10 and a process equipment 20.

The equipment front end module 10 is installed in front of the process equipment 20 to carry a wafer W between the process equipment 20 and a container 16 in which wafers W are housed. The equipment front end module 10 includes a plurality of loadports 12 and a frame 14. The container 16 is located on the loadport 12 by transporting means (not shown) such as an overhead transfer, an overhead conveyor or an automatic guided vehicle. The container 16 may be a closed container such as a front opened unified pod (FOUP). A frame robot 18 is installed inside the frame 14 to carry a wafer W between the process equipment 20 and the container 16 located on the loadport 12. A door opener (not shown) is installed inside the frame 14 to automatically open and close a door of the container 16. A fan filter unit (not shown) may be provided at the frame 14. The fan filter unit supplies clean air into the frame 14 to flow from an upper portion to a lower portion in the frame 14.

The process equipment 20 includes a loadlock chamber 22, a transfer chamber 24, and a process chamber 26. The transfer chamber 24 exhibits a polygonal shape, when view from the upside. The loadlock chamber 24 or the process chamber 26 is disposed at the side surface of the transfer chamber 24.

The loadlock chamber 22 is disposed at a side portion adjacent to the equipment front end module 10, among side portions of the transfer chamber 24, and the process chamber 26 is disposed at another side portion. One or at least two loadlock chambers 22 are provided. In an exemplary embodiment, two loadlock chambers 22 are provided. Wafers W put into the process equipment 20 to perform a process may be contained in one loadlock chamber 22, and wafers W processed to be taken out of the process equipment 20 may be contained in the other loadlock chamber 22. Alternatively, one or at least two loadlock chambers 22 may be provided and a wafer may be loaded or unloaded at the respective loadlock chambers 22.

Inside the loadlock chamber 22, wafers are vertically spaced to face each other. A plurality of slots 22a may be provided at the loadlock chamber 22 to support a portion of a wafer edge region.

The insides of the transfer chamber 24 and the process chamber 26 are kept sealed, and the inside of the loadlock chamber 22 is converted to vacuum and atmospheric pressure. The loadlock chamber 22 prevents external contaminants from entering the transfer chamber 24 and the process chamber 26. A gate valve (not shown) is installed between the loadlock chamber 22 and the transfer chamber as well as between the loadlock chamber 22 and the equipment front end module 10. In the case where a wafer W is carried between the equipment front end module 10 and the loadlock chamber 22, the gate valve installed between the loadlock chamber 22 and the transfer chamber 24 is closed. In the case where a wafer W is carried between the loadlock chamber 22 and the transfer chamber 24, the gate valve installed between the loadlock chamber 22 and the equipment front end module 10 is closed.

A process chamber 26 is provided to perform a predetermined process for a wafer W. The predetermined process includes processes using plasma such as, for example, an ashing process, a deposition process, an etching process or a cleaning process. In the event that a plurality of process chambers 26 are provided, each of the process chambers 26 may perform the same process for a wafer W. Optionally in the event that a plurality of process chambers 26 are provided, they may perform a series of processes for a wafer W. Hereinafter, a process chamber 26 performing a process using plasma will be referred to as a plasma treating apparatus.

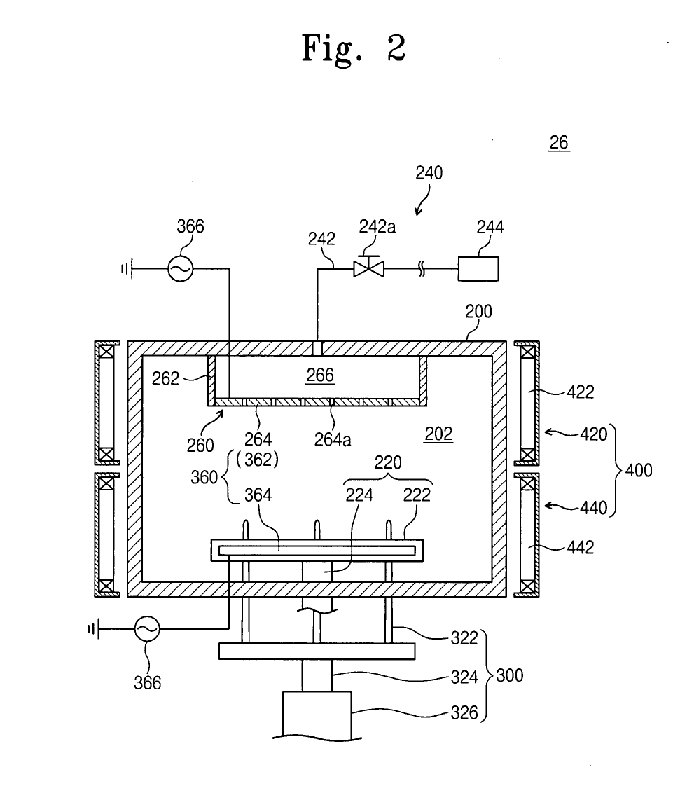

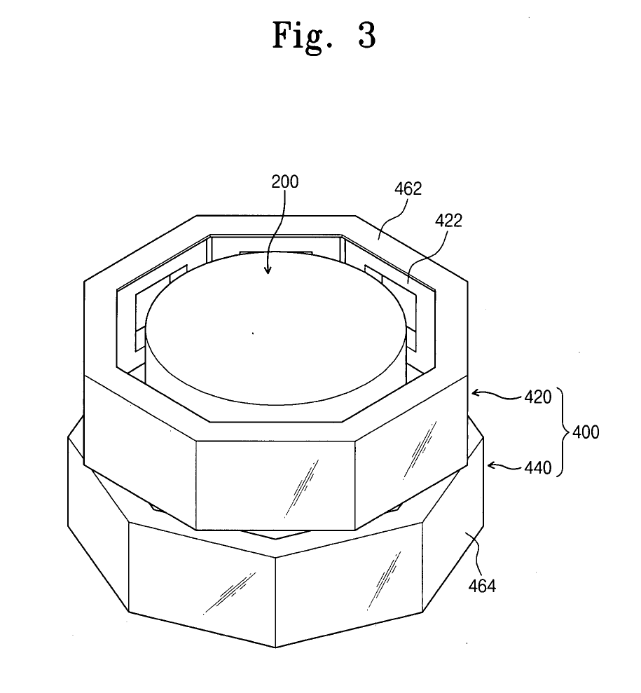

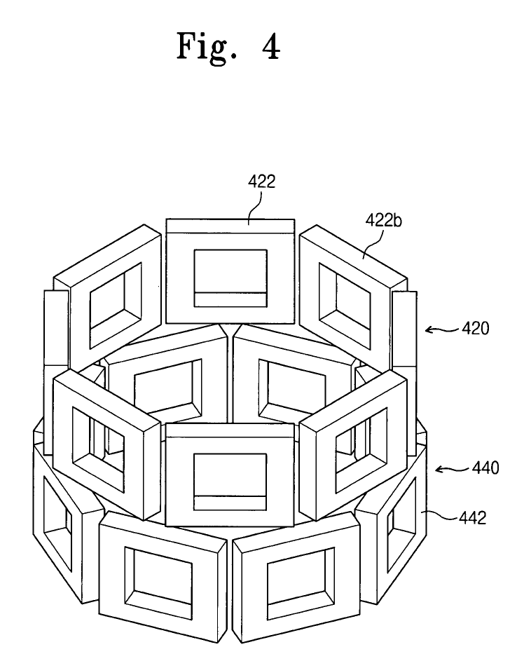

FIG. 2 is a cross-sectional view of the configuration of a plasma treating apparatus 26 for etching a wafer W, and FIG. 3 is a perspective view of FIG. 2. The plasma treating apparatus 26 includes a housing 200, a support member 220, a gas supply member 240, a shower head 260, a plasma source 360, and a magnetic field formation member 400. The housing 200 exhibits the shape of a cylinder in which defined is a space 202 where a process is performed. An exhaust pipe 292 is connected to a bottom wall of the hosing 200 to exhaust byproducts generated during a process. A pump 294 is installed at the exhaust pipe 292 to keep the inside of the housing 200 at a process pressure, and a valve 292a is installed at the exhaust pipe 292 to open or close an internal passage of inside the exhaust pipe 292.

The support member 220 includes a support plate 222 provided to support a wafer W during a process. The support plate 222 roughly exhibits the shape of a disk. A support shaft 224, which is rotatable by means of a motor 226, is fixedly coupled with a bottom surface of the support plate 222. A wafer W may rotate during a process. The support plate 222 may hold a wafer with the use of electrostatic force or mechanical clamping.

The gas supply member 240 is provided to supply a process gas into the housing 200. The gas supply member 240 includes a gas supply pipe 242 connecting a gas supply source 244 with the housing 200. A valve 242a is installed at the gas supply pipe 242 to open and close an internal passage.

The shower head 260 is provided to uniformly distribute a process gas flowing into the housing 200 to an upper region of the support member 220. The shower head 260 is disposed at an upper portion of the housing 200 to face the support plate 222. The shower head 260 includes an annular sidewall 262 and a circular injection plate 264. The sidewall 262 of the shower head 260 is fixedly coupled with the housing 200 to protrude downwardly from an upper wall of the housing 200. A plurality of injection holes 264a are formed at the entire region of the injection plate 264. The process gas is injected to a wafer W through the injection holes 264a after flowing into a space 266 defined by the housing 200 and the shower head 260.

A lift pin assembly 300 is provided to load a wafer W to the support plate 222 or to unload a wafer W from the support plate 222. The lift pin assembly 300 includes lift pins 322, a base plate 324, and a driver 326. The number of the lift pins 322 provided is three. The three lift pins 322 are fixedly installed at the base plate 324 to move with the base plate 324. The base plate 324 exhibits the shape of a disk and is disposed below the support plate 222 inside the housing 200 or outside the housing 200. The base plate 324 moves up and down by means of the driver 326 such as a hydraulic cylinder or a motor. The lift pins 322 are roughly disposed to correspond to apices of a regular triangle, when viewed from the upside. Through-holes are formed at the support plate 222 to vertically penetrate in an up-down direction. The lift pins 322 are inserted into the through-holes to move down via the through-holes, respectively. Each of the lift pins 322 exhibits the shape of a long rod, and the upper end thereof has an upwardly concave shape.

The plasma source 360 is provided to generate plasma from a process gas supplied to the upper region of the support plate 222. The plasma source 360 employs capacitively coupled plasma. The plasma source 360 includes a top electrode 362, a bottom electrode 364, and a power supply unit 366. An injection plate 264 of the shower head 260 is made of a metallic material and functions as the top electrode 362. The bottom electrode is provided at the inner space of the support plate 222. The power supply unit 366 applies a radio frequency power (RF power) or a microwave power to the top electrode 362 or the bottom electrode 364. The power supply unit 366 may apply a power to both of the top electrode 362 and the bottom electrode 364. Alternatively, a power may be applied to one of the top and bottom electrodes 362 and 364 and the other may be grounded.

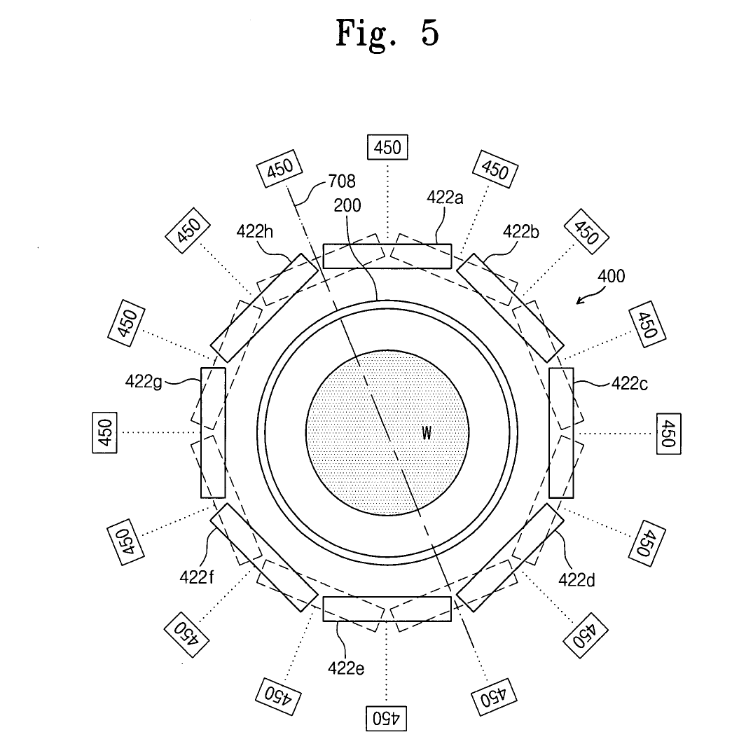

The magnetic field formation member 400 is disposed around the housing 200 to provide a magnetic field to a region where plasma is generated. FIG. 4 is a perspective view of a magnetic formation member 400, and FIG. 5 is a top plan view of FIG. 4. In FIG. 5, a first magnet unit 420 disposed at an upper region is represented by a solid line, and a second magnetic unit 440 disposed at a lower region is represented by a dotted line. Referring to FIGS. 4 and 5, the magnetic field formation member 400 includes a first magnet unit 420 and a second magnet unit 440. The first and second magnet units 420 and 440 are provided to form a layer. The first magnet unit 420 is disposed to surround an upper region among a side portion of the housing 200, and the second magnet unit 440 is disposed to surround a lower region among the side portion of the housing 200. The first magnet unit 420 includes a plurality of first magnets 422, and the second magnet unit 440 includes a plurality of second magnets 442.

An electromagnet is used as the respective first magnets 422 and the respective second magnets 442 to control direction and magnitude of a magnetic field. Accordingly, each of the first and second magnets 422 and 442 include coils. In this embodiment, the number of the first magnets 422 provided is eight and the number of the second magnets 442 provided is also eight. The magnets 422 and 442 exhibit the same shape. Each of the magnets 422 and 442 roughly exhibits the shape of rectangular ring and is disposed to stand upright. Inner side surfaces of the magnets 422 and 442 facing the housing 200 are provided flatly.

A power supply unit 450 is connected to the respective coils provided at the first and second magnets 422 and 442. It is assumed that, on the basis of any one of the first magnets 422 illustrated in FIG. 3, they are sequentially designated as a 1-1 magnet 422a, a 1-2 magnet 422b, a 1-3 magnet 422c, a 1-4 magnet 422d, a 1-5 magnet 422e, a 1-6 magnet 422f, a 1-7 magnet 422g, and a 1-8 magnet 422h. There are formed sets of magnets disposed to be symmetrical with respect to a line 708 running between the 1-1 magnet 422a and the 1-8 magnet 422h and between the 1-4 magnet 422d and the 1-5 magnet 422e. Currents having the same intensity are supplied in opposite directions to coils provided at the same set of magnets. The directions of current applied to the 1-1 through 1-4 magnets 422a, 422b, 422c, and 422d are identical to each other, and the directions of current applied to the 1-5 through 1-8 magnets 422e, 422f, 422g, and 422h are identical to each other. The intensity of current may be provided to decrease gradually as the current flows from the 1-1 magnet 422a to the 1-4 magnet 422d.

As mentioned above, in the case where current is applied, a nonlinear magnetic field line is formed toward the 1-8 magnet 422h from the 1-1 magnet 422a; a nonlinear magnetic field line is formed toward the 1-7 magnet 422g from the 1-2 magnet 422b; a nonlinear magnetic field line is formed toward the 1-6 magnet 422f from the 1-3 magnet 422c; and a nonlinear magnetic field line is formed toward the 1-5 magnet 422e from the 1-4 magnet 422d. The second magnets 442 are the same as the first magnets 422 and will not be described in detail.

A top frame 462 and a bottom frame 464 are provided around the housing 200 to exhibit the shape of octahedron. It appears that a through-hole is vertically formed at the center of the top and bottom frames 462. The bottom frame 464 is provided below the top frame 462. The first magnet 422 is fixedly installed at an inner side surface of the top frame 462, and the second magnet 442 is fixedly installed at an inner side surface of the bottom frame 464. The first magnets 422 are disposed to be spaced at regular intervals, and the second magnets 442 are also disposed to be spaced at regular intervals. Due to the above-described configuration, each of the first and second magnet units 420 and 440 roughly exhibits the shape of a regular octagon, when viewed from the upside.

The first and second magnetic units 420 and 440 are provided to be asymmetrical with respect to a horizontal surface running therebetween. In an embodiment, the second magnet unit 440 is provided to be in the state of rotating at a predetermined angle from a position where the first and second magnet units 420 and 440 are vertically aligned with each other. The predetermined angle is an angle except multiples of an interior angle of the first magnet unit 420 exhibiting a polygonal shape. The predetermined angle may be, for example, half of an interior angle. As described above, in the case where the first magnetic unit 420 exhibits the shape of a regular octagon, the second magnet unit 440 may be provided to be in the state of rotating at an angle of 67.5 degrees from a position where the first and second magnet units 420 and 440 are aligned with each other. Thus, the second magnets 442 are not aligned with the first magnets 422, and a second magnet 442 is disposed at a vertical lower portion between two first magnets 422.

A controller (not shown) controls the intensity and control of current applied to the coils of the first and second magnets 442 in the plasma treating apparatus. Also the controller controls the intensity of a power supplied to the plasma source 360. In addition, the controller controls general operations (e.g., transportation of a wafer W or process time) of the apparatus during a process.

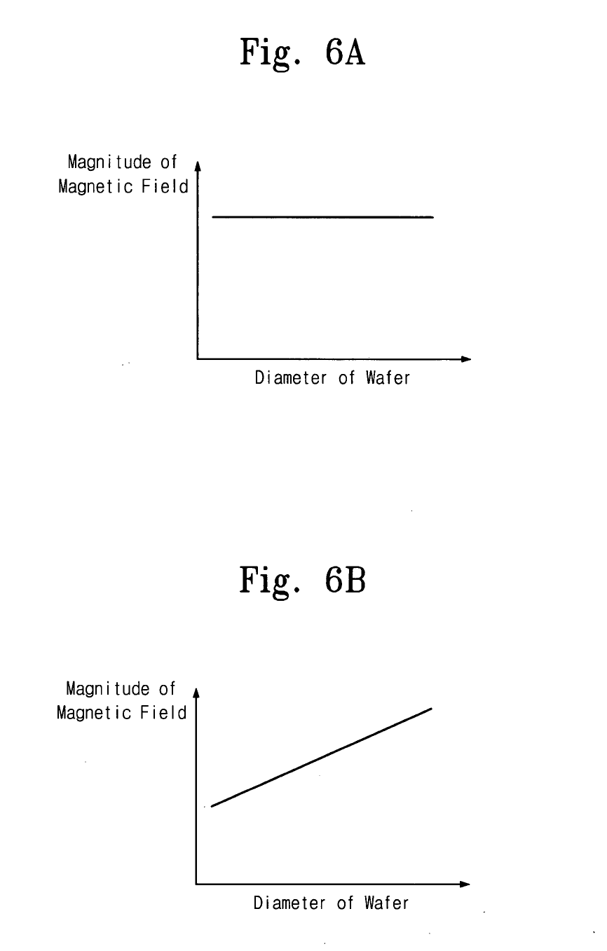

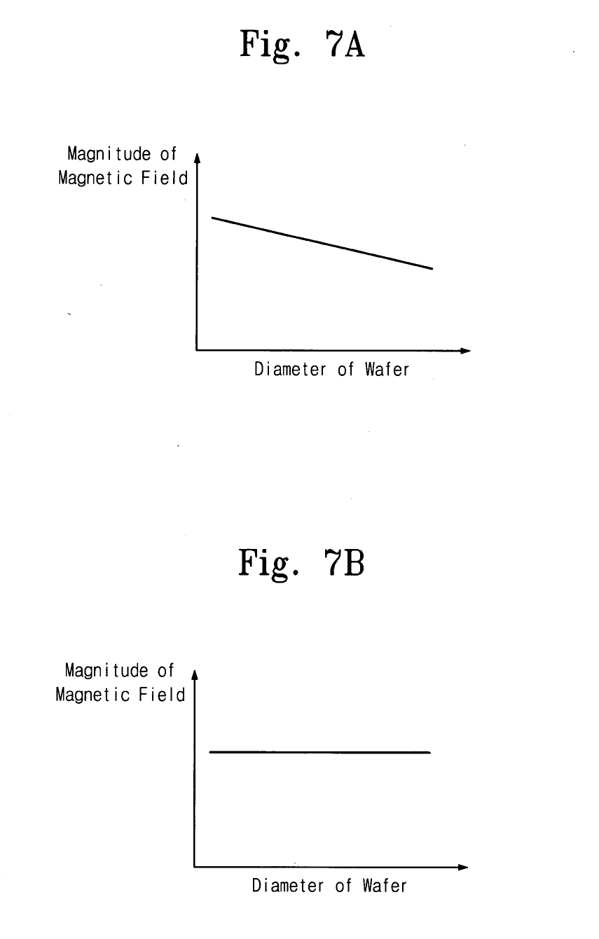

FIGS. 6A through 9C illustrate advantages obtained by using a magnetic field formation member 400 having the same configuration as described in the above embodiment. FIGS. 6A through 7B show the affect of uniformity of a magnetic field formed at an upper region of a wafer W inside a housing 200 on uniformity of plasma density (i.e., etching rate). As can be seen in FIGS. 6A and 6B, plasma density increases gradually in the case where a magnetic field is formed with uniform magnitude along the diameter of a wafer W. However, as can be seen in FIGS. 7A and 7B, plasma density is roughly uniform in the case where a magnetic field is formed with different intensities along the diameter of a wafer W. From FIGS. 6A through 7B, a difference between magnetic field intensities based on regions of a wafer W is a parameter to uniformly provide plasma density.

According to test where both end regions of the diameter of a wafer W and a central region of the wafer W were designated as A, B, and C regions, respectively, when the magnitude of a magnetic field decreased gradually along the A, B, and C regions, plasma density uniformity was excellent in the case where a ratio of a magnetic field magnitude at the A region to a magnetic field magnitude at the B region was within the range between 1.4 and 1.7.

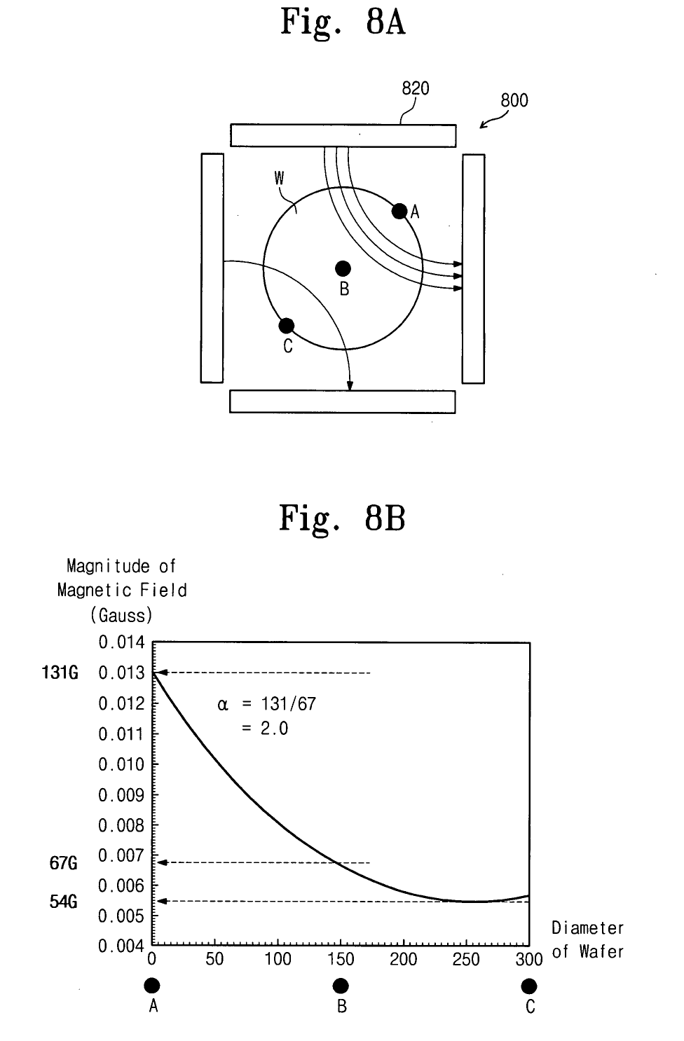

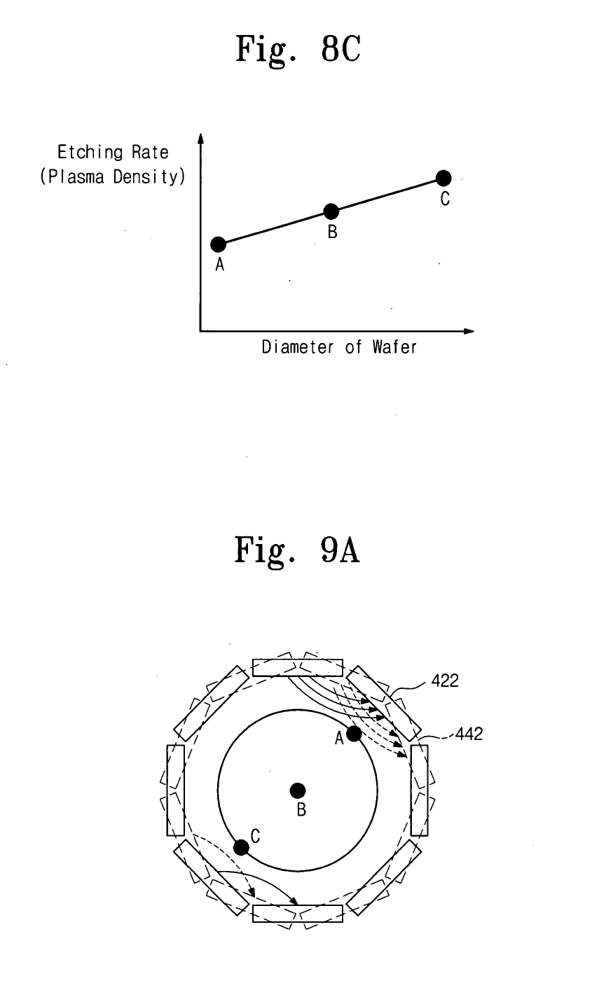

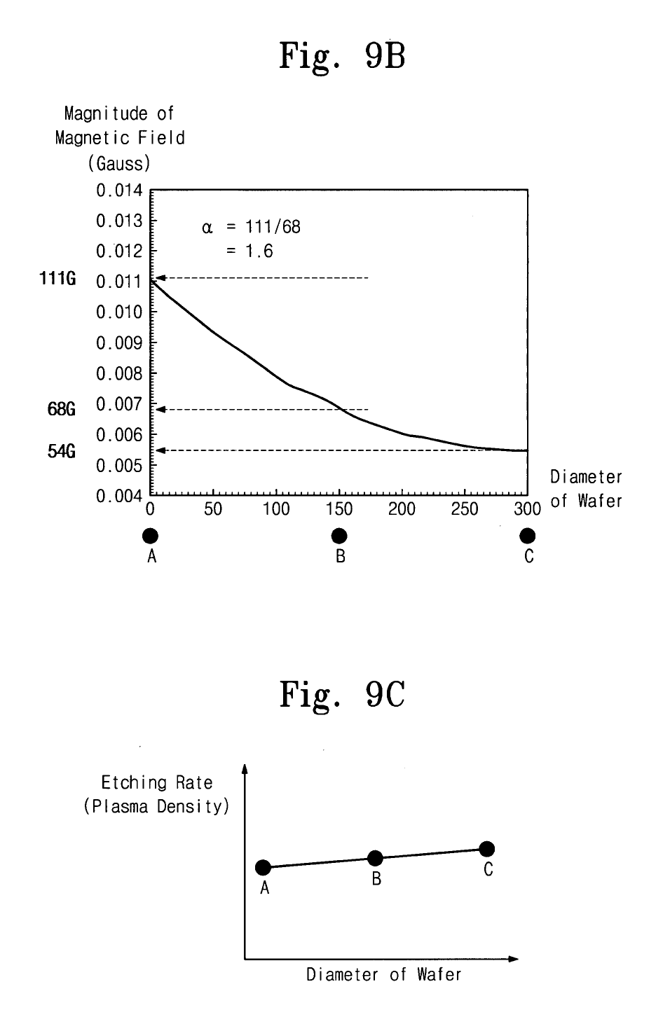

FIGS. 8A through 9C show magnetic field magnitude and plasma density inside a housing 200 according to the configuration of a magnetic field formation member. When using a magnetic field formation member 800 where electromagnets 820 are arranged as shown in FIG. 8A, a ratio of the magnetic field magnitude at an A region to the magnetic field magnitude at a B region is approximately 2.0 and uniformity of plasma density (etching rate) is slightly low. Although parameters affecting a magnetic field are variously altered, it is difficult to control the ratio and the uniformity within the foregoing range. However, when using the magnetic field formation member 400 as shown in FIG. 9A, a ratio of the magnetic field magnitude at an A region to the magnetic field magnitude at a B region is approximately 1.6 and uniformity of plasma density (etching rate) is significantly improved, as shown in FIG. 9C.

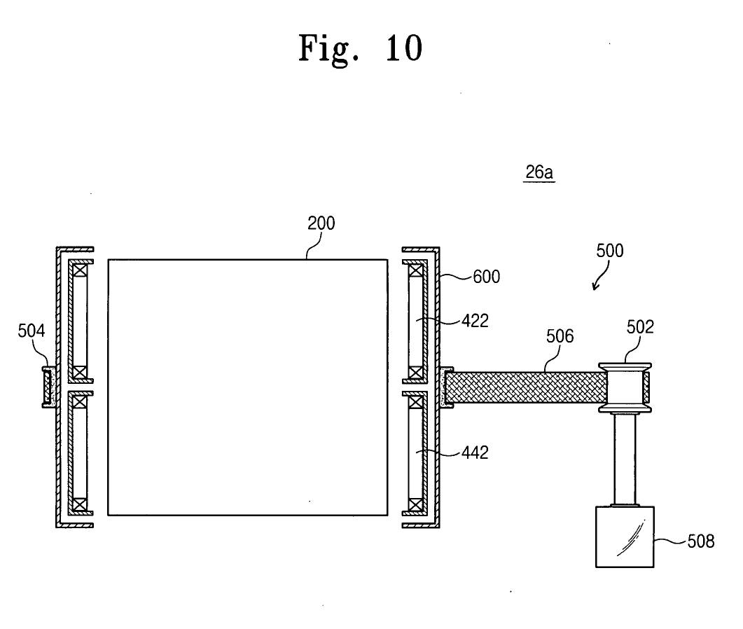

A rotation member 500 may be further provided at the plasma treating apparatus 26 to rotate the magnet units 420 and 440. FIG. 10 illustrates an example of a plasma treating apparatus 26a with a rotation member 500. A housing 200, and a plasma source 360 are identical to those described in the above embodiment and will not be described in further detail. A rotation cover 600 is installed outside the housing 200, and a through-hole is vertically formed at the rotation cover 600. Therefore, it appears that the rotation cover 600 is disposed to surround the housing 200. The rotation cover 600 exhibits the shape of a tube. A first magnet unit 420 and a second magnet unit 440 are fixedly installed inside the rotation cover 600.

The rotation member 500 rotates the first magnet unit 420 and the second magnet unit 440 at the same time. In an embodiment, the rotation member 500 includes a first pulley 502, a second pulley 504, a belt 506, and a motor 508. A rotation shaft of the motor 508 is fixedly installed at the first pulley 502, and the second pulley 504 is fixedly installed at the circumference of the rotation cover 600. The belt 506 is provided to roll up the first and second pulleys 502 and 504. A rotatory force of the motor 508 is transmitted to the rotation cover 600 through the first pulley 502, the belt 506, and the second pulley 504. The rotation member 500 serves to improve a uniformity of plasma density inside the housing 200 during a process. As described in the above embodiment, the rotation member 500 is provided as an assembly including a belt 506, pulleys 502 and 504, and a motor 508. However, the rotation member 500 may be any one of assemblies having various kinds of configurations.

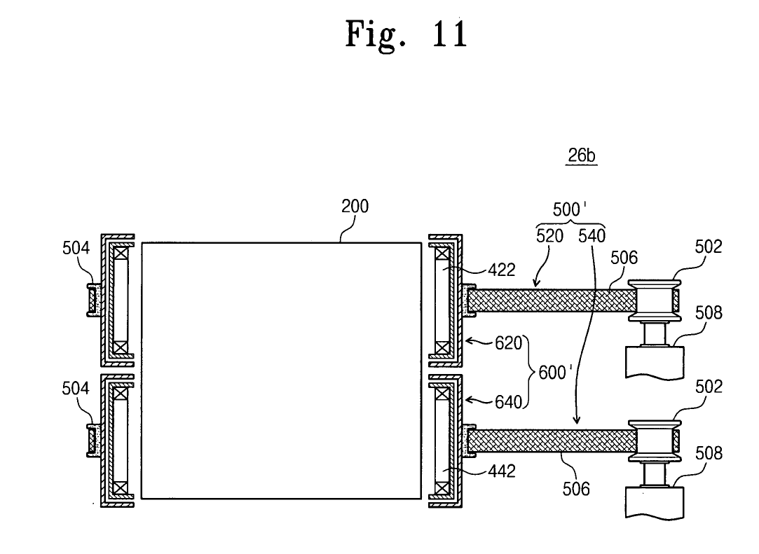

FIG. 11 illustrates another example of a plasma treating apparatus 26b with a rotation member 500′. A first rotation cover 620 and a second rotation cover 640 are installed outside a housing 200, and a through-hole is vertically formed at the first and second rotation covers 620 and 640. Therefore, it appears that the first and second rotation covers 620 and 640 are disposed to surround the housing 200. The first and second rotation covers 620 and 640 are provided with the same shape. The second rotation cover 640 is provided below the first rotation cover 620. A first magnet unit 420 is fixedly installed at the first rotation cover 620, and a second magnet unit 440 is fixedly installed at the second rotation cover 640.

The rotation member 500′ includes a first rotation unit 520 and a second rotation unit 540. The first rotation unit 520 rotates the first rotation cover 620 on its axis, and the second rotation unit 540 rotates the second rotation cover 640 on its axis. The rotation directions of the first and second rotation covers 620 and 640 may be identical to each other, and the rotation speeds thereof may be different from each other. Alternatively, the rotation directions of the first and second rotation covers 620 and 640 may be different from each other.

In the above embodiment, the rotation covers 620 and 640 are provided apart from frames 462 and 464. Alternatively, the frames 462 and 464 may be replaced with the rotation covers 620 and 640 without use of the rotation covers 620 and 640.

A typical apparatus uses various parameters to enhance a uniformity of plasma density. Among the parameters, parameters associated with the formation of a magnetic field are the number of electromagnets, the intensity of current applied to the respective electromagnets, and the direction of the applied current. However, this embodiment uses not only such well-known parameters but also additional parameters to make plasma density more uniform. The additional parameters are a misalignment degree (rotation angle) of a second magnet unit 440 to a first magnet unit 420 (they are provided to be partitioned by layers) and a relative rotation speed between the first and second magnet units 440 and 460.

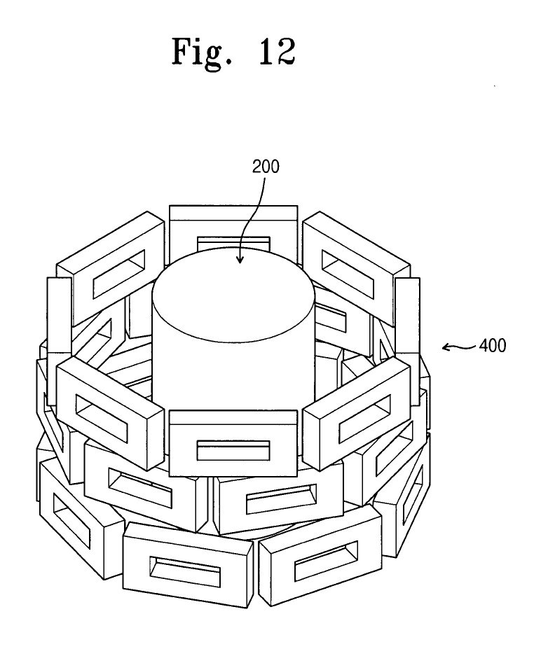

While it is described in the above embodiment that “the magnetic field supplying member 400 includes two magnet units 420 and 440 partitioned by layers”, the magnetic field formation member 400 may include at least three magnet units, as described in FIG. 12. In this case, adjacent magnet units may be disposed to be in the state of rotating at a predetermined angle from their aligned position, as described above embodiment.

While it is described in the above embodiment that “the magnetic field formation member 400 includes two magnet units 420 and 460 partitioned by layers”, the magnetic field formation member 400 may include at least three magnet units 420, 440, and 460, as described in FIG. 8. In this case, adjacent magnet units may be disposed to be in the state of rotating at a predetermined angle from their aligned position, as described above embodiment.

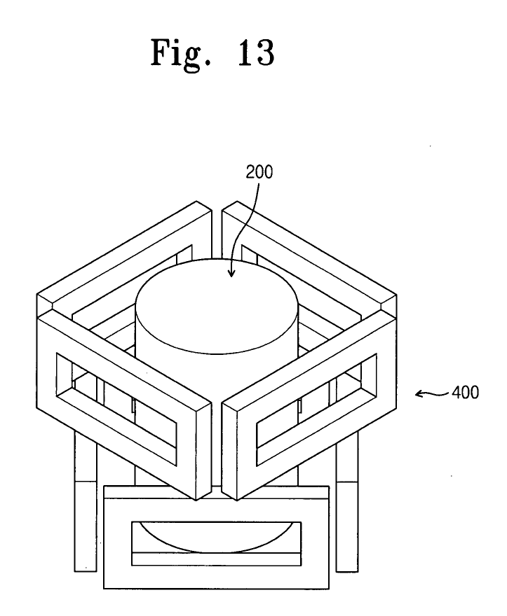

While it is described in the above embodiment that “the magnet units 420 and 440 include eight magnets 422 and 442, respectively”, the respective magnet units 420 and 440 may include different number of magnets 422 and 442 from the above number. For example, the magnet units 420 and 440 may include four magnets 422 and 442, respectively, as illustrated in FIG. 13.

While it is described in the above embodiment that “each magnet is an electromagnet”, each magnet may be a permanent magnet.

While it is described in the above embodiment that “each of the magnet units 420 and 440 is disposed to exhibit the shape of a regular polygon, when viewed from the above”, each of the magnet units 420 and 440 may be disposed to exhibit the shape of polygon or circle.

According to the present invention, plasma density is uniformly provided inside a housing and an etching uniformity is improved at the entire region of a wafer.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A plasma treating apparatus comprising:
a housing in which a space is provided to house a substrate;
a gas supply member provided to supply a gas into the housing;
a plasma source for generating plasma from the gas supplied into the housing; and
a magnetic field formation member provided to supply a magnetic field at a region where plasma is generated inside the housing,
wherein the magnetic field formation member comprises:
a first magnet unit disposed around the housing; and
a second magnet unit disposed around the housing and provide to be partitioned from the first magnet unit by a layer.

2. The plasma treating apparatus of claim 1, wherein the first magnet unit comprises a plurality of first magnets arranged to surround the housing and spaced apart from each other, and
wherein the second magnetic unit comprises a plurality of second magnets arranged to surround the housing and spaced apart from each other

3. The plasma treating apparatus of claim 2, wherein each of the first and second magnets is an electromagnet.

4. The plasma treating apparatus of claim 3, wherein the first and second magnetic units are disposed to be asymmetrical with respect to a horizontal surface running therebetween.

5. The plasma treating apparatus of claim 3, wherein the first and second magnets are disposed to deviate from their vertical alignment state.

6. The plasma treating apparatus of claim 3, wherein the first magnet unit is provided above the second magnet unit, and
wherein each of the second magnets is disposed below a portion between the adjacent first magnets.

7. The plasma treating apparatus of claim 6, wherein the respective first magnets and the respective second magnets are provided with the same shape, and the number of the first magnets is equal to that of the second magnets, and
wherein each of the second magnets is vertically disposed below a central position between the adjacent first magnets.

8. The plasma treating apparatus of claim 7, wherein each of the first and second magnets are provided to exhibit an rectangular ring shape.

9. The plasma treating apparatus of claim 8, wherein each of the first and second magnets has a flat surface facing the chamber.

10. The plasma treating apparatus of claim 7, wherein the number of the first magnets is even, and the number of the second magnets is even.

11. The plasma treating apparatus of claim 10, wherein the number of the first magnets is at least four, and the number of the second magnets is at least four.

12. The plasma treating apparatus of claim 3, wherein the first magnet unit is disposed such that the first magnets exhibit the shape of a regular polygon, when viewed from the upside, and the second magnet unit is disposed such that the second magnets exhibit the shape of a regular polygon, when viewed from the upside, and
wherein the second unit is disposed to rotate on its axis with respect to the first magnet unit at an angle except multiples of an interior angle of the regular polygon.

13. The plasma treating apparatus of claim 3, wherein the magnetic field formation member further comprises a third magnet unit including a plurality of third magnets is disposed around the housing and provided to be partitioned from the first and second magnet units by layers.

14. The plasma treating apparatus of claim 3, further comprising:
a rotation member configured to rotate the magnetic field formation member on the axis of the rotation member.

15. The plasma treating apparatus of claim 3, further comprising:
a first rotation unit configured to rotate the first magnet unit; and
a second rotation unit configured to rotate second magnet unit independently of the first magnet unit.

16. A plasma treating apparatus comprising:
a housing where a plasma process is performed;
a plasma source provided into the housing to generate plasma from a gas supplied into the housing; and
at least two magnet units disposed to surround the circumference of the housing and provided to be partitioned by layers,
wherein each of the magnet units includes a plurality of electromagnets disposed to exhibit a shape surrounding a lateral portion of the housing, and
wherein the electromagnets provided at adjacent layers are arranged to be asymmetrical with respect to a surface running between the electromagnets.

17. The plasma treating apparatus of claim 16, wherein magnets provided at any one of the magnet units are disposed between adjacent magnets of an overlying magnet unit.

18. The plasma treating apparatus of claim 16, wherein each of the magnet units is disposed to exhibit the shape of a polygon, when viewed from the upside.

19. The plasma treating apparatus of claim 16, wherein each of the magnet units is disposed to exhibit the shape of a regular polygon, when viewed from the upside, and one of the magnet units is disposed to rotate with respect to another adjacent magnet unit at an angle that is different from N times (N being an integer) of an internal angle of the regular polygon.

20. The plasma treating apparatus of claim 19, further comprising:
a rotation member configured to rotate magnet units.

21. The plasma treating apparatus of claim 19, further comprising:
a rotation member configured to rotate the magnetic units independently of each other.
